(19) United States
(12) Patent Application Publication
(10) Pub. No.: US 2006/0231889 A1
(43) Pub. Date: Oct. 19, 2006

(54) Two-terminal solid-state memory device and two-terminal flexible memory device based on nanocrystals or nanoparticles

(76) Inventors: Tupei Chen, Singapore (SG); Yang Liu, Singapore (SG); Chi Yung Ng, Singapore (SG); Man Siu Tse, Singapore (SG)

Correspondence Address: BLAKELY SOKOLOFF TAYLOR & ZAFMAN, 12400 WILSHIRE BOULEVARD, SEVENTH FLOOR, LOS ANGELES, CA, 90025-1030, US

(21) Appl. No.: 11/106,195

(22) Filed: Apr. 13, 2005

(51) Int. Cl. H01L 29/792

(52) U.S. Cl. 257/325

(57) ABSTRACT

A two-terminal memory device based on semiconductor (such as Si or Ge) or metal (such as Al or Au) nanocrystals and/or nanoparticles is described wherein each device has a substrate, a dielectric layer (such as SiO₂ or organic dielectric materials) nanocrystals and/or nanoparticles distributed throughout the dielectric layer, and a metal (or poly-crystalline Si, or conductive organic materials) gate electrode. The memory states of the device are distinguished by charging and discharging the nanocrystals and/or nanoparticles. This two-terminal memory device is much simpler than the conventional four-terminal MOSFET-based memory device in terms of device structure and fabrication process. In addition, it is flexible if the memory devices are fabricated on flexible substrate with organic materials.

### BACKGROUND

1. Field

Embodiments of the present invention relate to memory devices and in particular to two-terminal memory devices.

2. Discussion of Related Art

In recent years, it is found that semiconductor nanocrystals are effective in storing electric charges, which has been proposed as a basis for the development of nonvolatile memory devices. Commonly used approach for fabricating such memory devices is based on conventional MOSFET processes. The resulting devices include a substrate with source and drain regions, a gate oxide above the substrate with nanocrystals (<10 nm) embedded in 2-3 nm close to the substrate. The advantage of this type of device is that nonvolatile memories can be formed, particularly devices of ultra-low power consumption, ultra-high density in the chip and with simpler design. Examples are described in U.S. Pat. No. 6,320,784 to Muralidhar et al. and U.S. Pat. No. 6,690,059 to Lojek.

However, there are many times of photolithography in fabricating MOSFETs and the structures around the nanocrystals. The resolution of photolithography will limit the dimensions of the device and thus the device density in the chip. Therefore, it would be attractive to provide nanocrystal-based memory devices that are with simpler design and fabrication techniques.

### SUMMARY

The above object has been realized in a MOS structure with a high concentration of nanocrystals embedded throughout the gate oxide wherein the previous problems are eliminated. In contrast to the conventional situation in which charge trapping in nanocrystals confined in a narrow layer embedded in the gate oxide of MOSFETs leads to a shift in threshold voltage, charge trapping in nanocrystals distributing throughout the gate oxide of MOS devices in the present invention leads to modulations in capacitance, gate oxide resistance, and gate current. The modulated capacitance, gate oxide resistance, and gate current can be recovered after the release of the trapped charges. These modulations, especially the gate oxide resistance modulation, allow the device to behave as “on” or “off” state. And as such a memory structure has only two terminals, i.e., the gate and the substrate (here no source and drain terminals are required), it can be fabricated with a simpler design and less fabrication steps. Furthermore, the device density in a chip can be substantially increased because of the use of the two-terminal devices with elimination of source/drain areas.

In addition to the above two-terminal solid-state memory device, a two-terminal flexible memory device can be also realized based on the same idea by using organic dielectric layer, organic conductive layer and organic semiconductor layer deposited on a flexible substrate.

### BRIEF DESCRIPTION OF THE DRAWINGS

In the drawings, like reference numbers generally indicate identical, functionally similar, and/or structurally equivalent elements. The drawing in which an element first appears is indicated by the leftmost digit(s) in the reference number, in which:

FIG. 1 is a cross section view of the two-terminal solid-state memory device according to an embodiment of the present invention;

FIG. 2 is a flowchart illustrating an approach to fabricating the two-terminal solid-state memory device depicted in FIG. 1 according to an embodiment of the present invention;

FIG. 3 is a graph showing the discharged and charged states in a time-domain capacitance measurement at −0.5V of the device depicted in FIG. 1 according to an embodiment of the present invention;

FIG. 4 is a graph showing the discharged and charged states in a time-domain resistance measurement at 0.5V of the device depicted in FIG. 1 according to an alternative embodiment of the present invention;

FIG. 5 is a graph showing the discharged and charged states in a C-V measurement of the device depicted in FIG. 1 according to an embodiment of the present invention;

FIG. 6 is a graph showing the discharged and charged states in a voltage-dependent gate current measurement;

FIG. 7 is a graph showing discharged and charged states in a voltage-dependent gate resistance measurement of the device depicted in FIG. 1 according to an embodiment of the present invention;

FIG. 8 is a cross section view of a two-terminal flexible memory device made of organic materials according to an alternative embodiment of the present invention;

FIG. 9 is a flowchart illustrating an approach to fabricating the two-terminal solid-state memory device depicted in FIG. 8 according to an embodiment of the present invention; and

FIG. 10 is a flowchart illustrating a method of operating the two-terminal solid-state memory device depicted in FIG. 1 and/or FIG. 8 according to an embodiment of the present invention.

### DETAILED DESCRIPTION OF THE ILLUSTRATED EMBODIMENTS

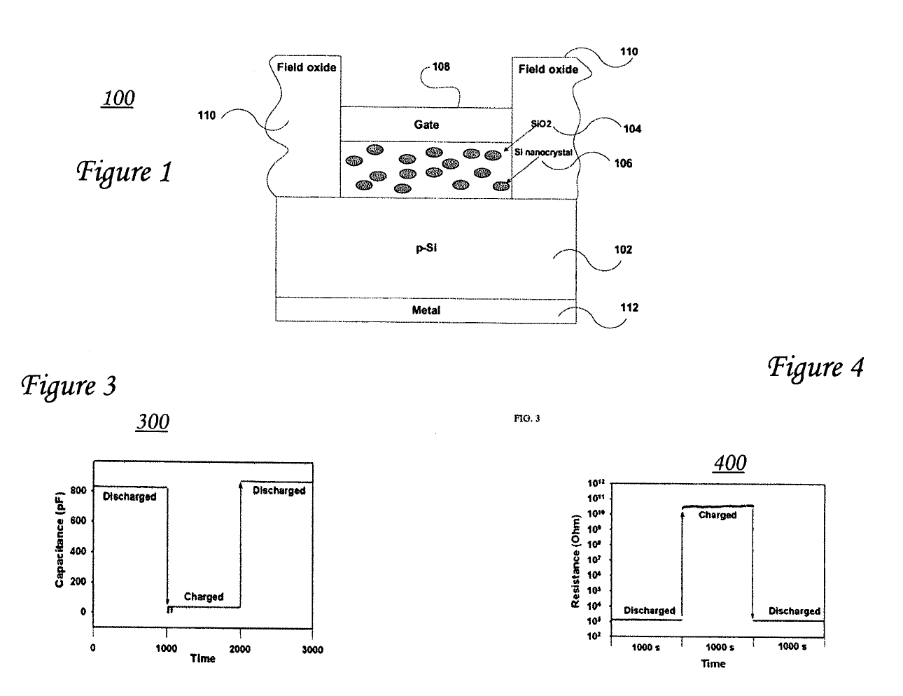

FIG. 1 is a cross section view of a two-terminal solid-state memory device 100 according to an embodiment of the present invention. In the illustrated embodiment, the device 100 includes a substrate 102, a dielectric layer 104 disposed on the substrate 102, several nanocrystals and/or nanoparticles 106 disposed in the dielectric layer 104, a gate electrode 108 disposed on the dielectric layer 104, and an insulating layer 110 disposed on the substrate 102. A metal electrode 112 may be disposed on the backside of the substrate 102 as the second terminal.

In embodiments of the present invention, the nanocrystals and/or nanoparticles 106 are distributed throughout the dielectric layer 104. In one embodiment, the peak concentration of nanocrystals and/or nanoparticles 106 may be located near the gate electrode 108.

In one embodiment, the substrate 102 may be a p-type semiconductor substrate, such as (100) silicon (Si), for example. In an alternative embodiment, the substrate 102 may be any other suitable semiconductor substrates.

In one embodiment, the dielectric layer 104 may include silicon oxide (SiO₂). In alternative embodiments, the dielectric layer 104 may include other suitable dielectric materials.

In some embodiments, the nanocrystals and/or nanoparticles 106 may include a semiconductor material such as silicon (Si) and/or germanium (Ge), for example, having a peak concentration located proximate to the gate electrode 108. In other embodiments, the nanocrystals and/or nanoparticles 106 may include a metals such as gold (Au) and/or aluminum (Al), for example. In embodiments, the nanocrystals and/or nanoparticles 106 may have a size in the range of approximately one to one hundred nanometers (1-100 nm).

In embodiments of the present invention, the gate electrode 108 may include metal such as aluminum (Al), gold (Au), silver (Ag), and/or copper (Cu). In alternative embodiments, the gate electrode 108 may include polysilicon, indium tin oxide (ITO), and/or zinc oxide (ZnO).

In one embodiment, the insulating layer 110 may be any suitable field oxide (hereinafter “field oxides 110”).

In one embodiment, the metal electrode 112 may be any suitable metal, such as aluminum (Al), gold (Au), silver (Ag) and copper (Cu), for example.

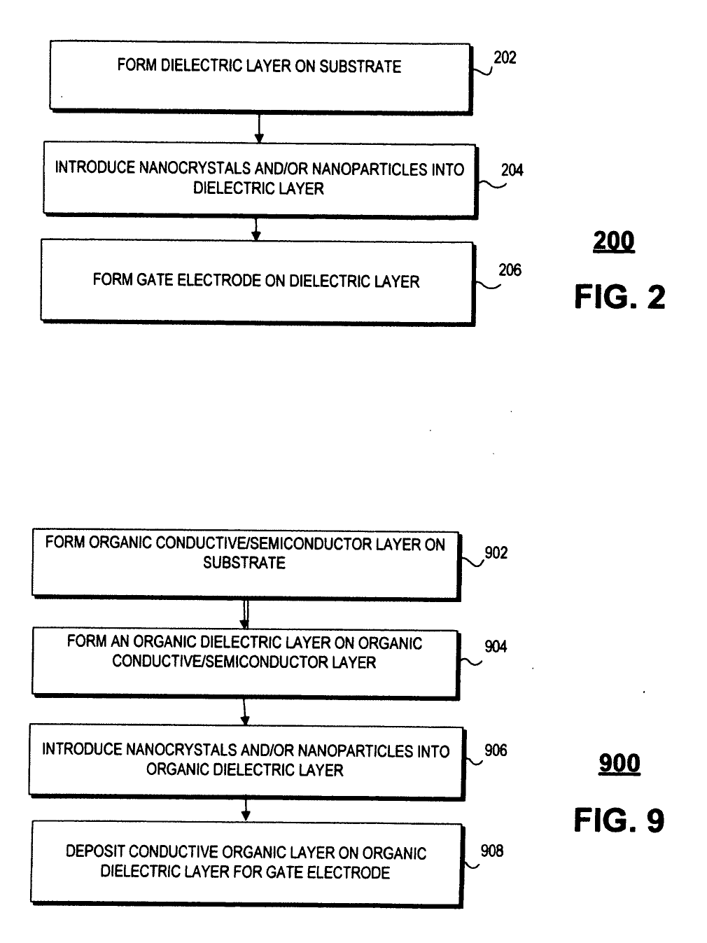

FIG. 2 is a flowchart illustrating a method 200 of fabricating the device 100 according to an embodiment of the present invention. In a block 202, the dielectric layer 104 may be formed on the substrate 102. In one embodiment, the substrate 102 may be doped in a way common to fabrication of a metal oxide semiconductor (MOS) device. The field oxides 110 may be grown on the substrate 102 to define the active area of the device 100. In alternative embodiments, other methods for isolation of the device 100, such as shallow trench isolation (STI) and/or local oxidation of silicon (LOCOS), for example, also may be used. Before formation of the dielectric layer 104, the substrate 102 may be cleaned using a standard CMOS process.

The dielectric layer 104 may then be thermally grown on the substrate 102. In one embodiment, a thirty nanometer (30 nm) silicon dioxide (SiO₂) film may be thermally grown on P-type (100) Si wafers in dry oxygen at 950° C.

In a block 204, nanocrystals and/or nanoparticles 106 may be introduced into the dielectric layer 104. In one embodiment, following cleaning and growing of the dielectric layer 104 ions may be implanted in the dielectric layer 104. The acceleration energy may be such that implanted atoms distribute throughout the dielectric layer 104 and exist to a depth of a few nanometers within the substrate 102. In one embodiment, the ions may be silicon (Si). In alternative embodiments, the ions may be other semiconductors, such as germanium (Ge), for example. In still other embodiments, other ion species such as as gold (Au) and/or aluminum (Al), for example, may be implanted in the dielectric layer 104. The dose and energy used for implantation may be determined experimentally according to the thickness of the dielectric layer 104.

In one embodiment, a dose of silicon (Si) of approximately 3×10¹⁶atoms/cm² at 14 KeV may be used to introduce the nanocrystals and/or nanoparticles 106 into a dielectric layer 104 of approximately thirty nanometers (30 nm) thick. Thermal annealing may be carried out at 1000° C. in N₂ ambient for 1 hour to induce formation of the nanocrystals and/or nanoparticles 106. Annealing may also eliminate the damage/defects caused by ion implantation. In one embodiment, the mean size of nanocrystals and/or nanoparticles 106 may be approximately four nanometers (4 nm) as determined from x-ray diffraction measurement, for example.

In alternative embodiments, other techniques may be used to introduce the nanocrystals and/or nanoparticles 106 into the dielectric layer 104. For example plasma enhanced chemical vapor deposition (PECVD) may be used to embed the nanocrystals and/or nanoparticles 106 in the dielectric layer 104. Next, high-temperature thermal annealing in inert ambient is carried out to induce the formation of nanocrystals.

After embedding the nanocrystals and/or nanoparticles 106 in the dielectric layer 104 is accomplished, the surface of the dielectric layer 104 that includes a comparatively low concentration of nanocrystals and/or nanoparticles 106 may be removed using a hydrofluoric acid (HF) solution of approximately 50:1, for example. For example, in embodiments in which the dielectric layer 104 is grown to a thickness of approximately thirty nanometers (30 nm) the top seventeen nanometers (17 nm) of the dielectric layer 104 may be removed to leave a high concentration of nanocrystals and/or nanoparticles 106 distributed throughout the dielectric layer 104 and/or a peak concentration located close to the surface of the dielectric layer 104 nearest the gate electrode 108.

In a block 206, the gate electrode 108 may be formed. In one embodiment, a layer of metal may be deposited on the dielectric layer 104 and an electrode mask may be selected to define the gate electrode 108. A layer of metal 112 may be deposited on the backside of the substrate 102 as the second terminal after removing backside oxide. Standard metal alloy process may then be conducted to form ohmic contacts for the device 100.

In one embodiment, a twenty nanometer (20 nm) aluminum layer may be deposited on the dielectric layer 104 to form the gate electrode 108. The wafer backside may be coated with a layer of aluminum with the thickness of about 1 μm after removing the backside oxide. Metal alloy process may be conducted at 425° C. in N₂ ambient to form ohmic contacts.

FIG. 3 is a graphical representation 300 showing the discharged and charged states in a time-domain capacitance measurement at −0.5V of the device 100 according to an embodiment of the present invention. The measurements were conducted with the device 100 at room temperature. The graphical representation 300 illustrates that in contrast to the conventional case, there is capacitance magnitude modulation between the charged and the discharged states. As can be seen in graphical representation 300, in this embodiment, the MOS capacitance between the dielectric layer 104 and the gate electrode 108 is reduced dramatically from the initial value of ˜830 pF to a very low level (<40 pF). In other words, the electrical state of the device 100 was switched from a discharged state (high-capacitance state) to a charged state (low-capacitance state). With release of the charges, the device 100 was switched to the next discharged state (high-capacitance state) of ˜870 pF. In embodiments, the modulation ratio may be ˜20 in the capacitance between the discharged and charged states.

FIG. 4 is a graphical representation 400 showing the discharged and charged states in a time-domain resistance measurement at 0.5V of the device 100 according to an alternative embodiment of the present invention. In the illustrated embodiment, the direct current (DC) resistance of device 100 shows a significant difference between a charged state (high-resistance state) and a discharged state (low-resistance state). The resistance illustrated is ˜3×10¹⁰ ohm for the charged and ˜1.3×10³ ohm for the discharged state. This indicates that the example resistance ratio between the two states is ˜2×10⁷.

With such high capacitance ratios illustrated in FIG. 3 or high resistance ratios illustrated in FIG. 4, memory states (i.e., the charged and discharged states) can be easily distinguished. Specially, the huge difference in DC resistance between the memory states allows the device 100 to behave as an excellent switch with well-distinguished “on” and “off” states. Furthermore, the memory states may be retained for at least a few hours at low voltage (such as less than one volt, for example), as there are no significant changes in the capacitance and/or resistance of the charged or discharged states observed during the time frame of the limit of the measurements. This means that the memory states may be detected easily by a low sense voltage but may not be changed by the detection itself.

In embodiments of the present invention, the low-resistance/high-resistance states may be attributed to the on/off of the electron tunneling paths formed by the nanocrystals and/or nanoparticles 106 as a result of electron detrapping/trapping in the nanocrystals and/or nanoparticles 106. The electron trapping and detrapping correspond to the charged and discharged memory states, respectively. In the discharged state, most of the nanocrystals and/or nanoparticles 106 may be uncharged, and thus many tunneling paths connecting the substrate 102 to the gate electrode 108 may be formed leading to a low resistance between the gate electrode 108 and the substrate 102. However, in the charged state, most of the nanocrystals and/or nanoparticles 106 may charged up, electron tunneling may be blocked by the trapped electrons, and thus there may be very few tunneling paths connecting the substrate 102 to the gate electrode 108. Therefore, the resistance of the charged state may be very high. On the other hand, for a single nanocrystal and/or nanoparticle 106, it has a capacitance C_{nc}^{j}, and its resistance to the gate electrode 108 and the substrate 102 is represented with R₁^{j} and R₂^{j}, respectively. Thus, its equivalent frequency-dependent capacitance Cₚ^{j}(ω) in C-V measurement can be expressed as

$${C}_{P}^{j} ( ω ) = \frac{{C}_{nc}^{j}}{1 + {[ ω ( {R}_{1}^{j} + {R}_{2}^{j} ) {C}_{nc}^{j} ]}^{2}} .$$

With all nanocrystals and/or nanoparticles 106 embedded in the SiO₂ matrix (i.e., the dielectric layer 104 with the nanocrystals and/or nanoparticles 106) taken into account, the total frequency-dependent capacitance

$${C}_{P} ( ω ) = {\sum }_{j = 1}^{N} {C}_{P}^{j} ( ω ) ,$$

where N is the number of the nanocrystals and/or nanoparticles 106 in the SiO₂ matrix. Therefore, for the charged state, as most of the nanocrystals and/or nanoparticles 106 are charged up, the resistance (R₁^{j} and R₂^{j}) for every nanocrystal and/or nanoparticle 106 should be extremely high due to the lack of tunneling paths, and thus the total capacitance C_{P}(ω) is small. However, for the discharged state, the resistance (R₁^{j} and R₂^{j}) for every nanocrystals and/or nanoparticles 106 should be low due to the existence of many tunneling paths as most of nanocrystals and/or nanoparticles 106 are uncharged, and thus the total capacitance C_{P}(ω) should be large.

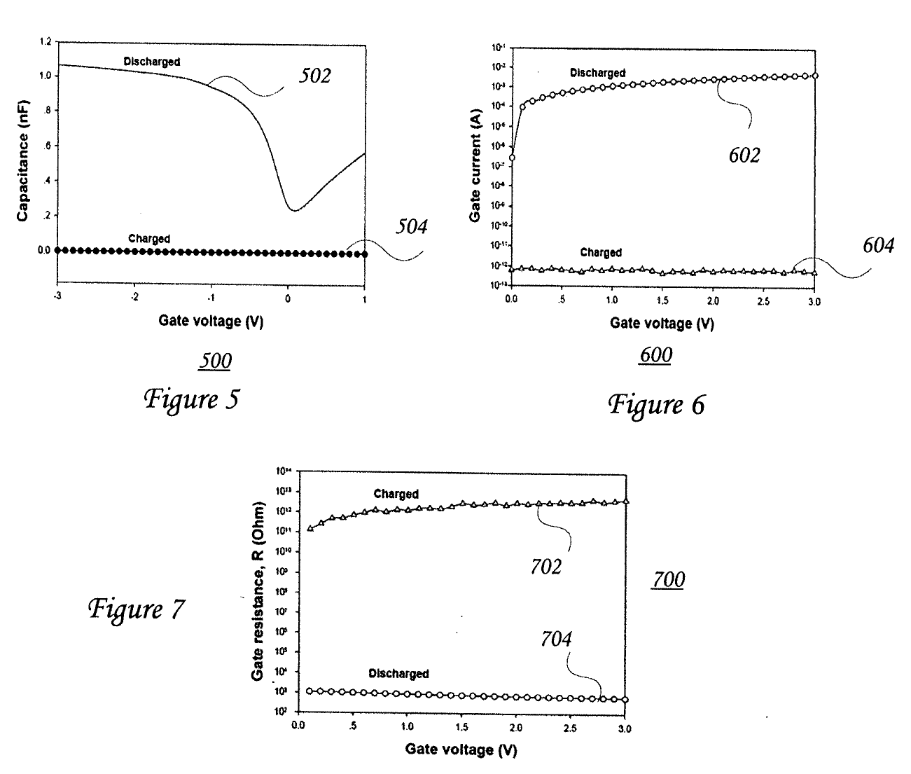

FIG. 5 is a graphical representation 500 illustrating the discharged and charged states in a capacitance-voltage (C-V) measurement of the device 100 according to an embodiment of the present invention. The measurement may be taken across terminals 108 and 112. In the example graphical representation 500, the ordinate represents the capacitance and the abscissa represents gate voltage. The measurement illustrated in the graphical representation 500 was conducted with the device 100 at room temperature in the laboratory. In the example graphical representation 500, a curve 502 represents the capacitance-voltage characteristic of the device 100 under the uncharged state, while the curve 504 represents the capacitance-voltage characteristics of the device 100 under the charged state. As shown in FIG. 5, there is a large change in C-V characteristics between the charged and discharged states. At a low sense voltage of 0.5V, for example, the capacitance under the discharged and charged states may be 400 pF and 600 fF, respectively, showing a capacitance ratio of ˜670 between the two states.

FIG. 6 is a graphical representation 600 illustrating the discharged and charged states in a voltage-dependent gate current measurement of the device 100 according to an embodiment of the present invention. The measurement may be taken across terminals 108 and 112. In the example graphical representation 600, the ordinate represents the gate current and the abscissa represents gate voltage. The measurement illustrated in the graphical representation 600 was conducted with the device 100 at room temperature in the laboratory. In the example graphical representation 600, a curve 602 represents the voltage-dependent gate current measurement of the device 100 under the uncharged state, while the curve 604 represents the voltage-dependent gate current measurement of the device 100 under the charged state. At a sense voltage of 0.5V, for example, the gate current of the device 100 at a discharged state is 5×10⁻⁴ amperes (A), and the current of the charged state is nine orders lower than that of the discharged state.

FIG. 7 is a graphical representation 700 illustrating the discharged and charged states in a voltage-dependent gate resistance measurement of the device 100 according to an embodiment of the present invention. The measurement may be taken across terminals 108 and 112. In the example graphical representation 700, the ordinate represents voltage applied to the gate and the abscissa represents the resistance. The measurement illustrated in the graphical representation 700 was conducted with the device 100 at room temperature in the laboratory. In the example graphical representation 700, a curve 702 represents the voltage-dependent gate resistance measurement of the device 100 under the charged state, while the curve 704 represents the voltage-dependent gate resistance measurement of the device 100 under the uncharged state. At a sense voltage of 0.5 V, for example, the gate oxide resistance is at the order of 10³ ohms under the uncharged state and the resistance is increased to the order of 10¹¹ ohms under the charged state. Thus, a resistance ratio of more than 10⁸ can be obtained.

The capacitance and the resistance are directly related to the charge trapping/detrapping in the nanocrystals. The amount of the trapped charges and the trapping sites are not necessarily the same for every charging/discharging operation since charge trapping/detrapping is a random process. Therefore, the capacitance and the resistance are not necessarily the same for every charging/discharging operation. However, the difference in the capacitance or resistance between a charged state and a discharged is typically large enough such that the two memory states are distinguishable. For example, as shown in the graphical representation 300, although there is a small difference in the capacitance between the first discharged state and the repeated discharged state, both the first discharged state and the repeated discharged state can be well distinguished from the charged state.

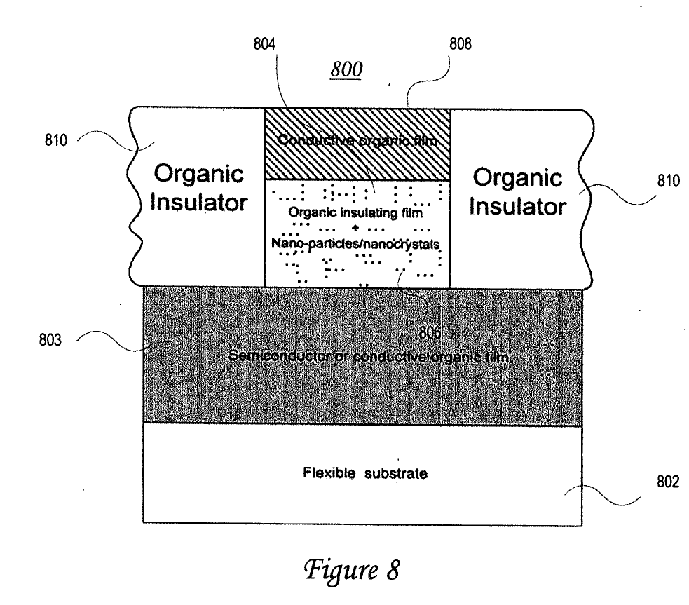

FIG. 8 shows a cross section view of a two-terminal flexible memory device 800 realized with organic materials according to an alternative embodiment of the present invention. In the illustrated embodiment, the device 800 includes a flexible substrate 802, an organic semiconductor or organic conductive layer 803 disposed on the flexible substrate 802, an organic insulating film 804 disposed on the layer 803, several nanocrystals and/or nanoparticles 806 disposed in the organic insulating film 804, a conductive organic film 808 disposed on organic insulating film 804, and an organic insulator 810 disposed on the organic semiconductor or organic conductive layer 803.

FIG. 9 is a flowchart illustrating an approach to fabricating the two-terminal solid-state memory device 800 according to an embodiment of the present invention. In a block 902, the organic semiconductor or organic conductive layer 803 is deposited on the flexible substrate. In one embodiment, the organic semiconductor or organic conductive layer 803 may be deposited by vapor deposition, solution deposition, or spin coating. Organic semiconductors such as anthracene, tetracene, and pentacene may be used. In one embodiment, the flexible substrate 802 may be formed of polymeric materials. In another embodiment, the flexible substrate 802 may be formed of fiber-reinforced plastics (FRP) to allow for roll processing without breaking and distorting.

In a block 904, the organic dielectric/insulating layer 804 may be formed on the organic semiconductor or organic conductive layer 803. In one embodiment, organic dielectric/insulating layer 804 may be synthesized with a number of organic polymers considered as dielectric materials, such as polyimides, and parylene C, by solution coating techniques or other suitable techniques.

In a block 906, nanoparticles and/or nanocrystals 806 may be introduced into the organic dielectric/insulating layer 804. In embodiments, the nanoparticles and/or nanocrystals 806 may be embedded throughout the organic dielectric/insulating layer 804. For example, nanopowders such as metal and/or semiconductor powders with a particle size-on a nanoscale, for example, may be doped into the solutions that will be used to synthesize the organic dielectric/insulating layer 804. Alternatively, metal or semiconductor ions may be implanted into the organic dielectric/insulating layer 804 with the dose and energy determined experimentally.

In a block 908, the conductive organic film 808 may be deposited on organic insulating film 804. In one embodiment, conductive polymers, such as polyaniline, for example, may be used for both the conductive organic film 808 (gate electrode 808) and the organic semiconductor or organic conductive layer 803 in the device 800.

In one embodiment of the present invention, the operation mechanism and electrical characteristics for the device 800 are the same as or similar to those of the device 100. Realization of the device 800 allows for flexible memory applications with very low cost.

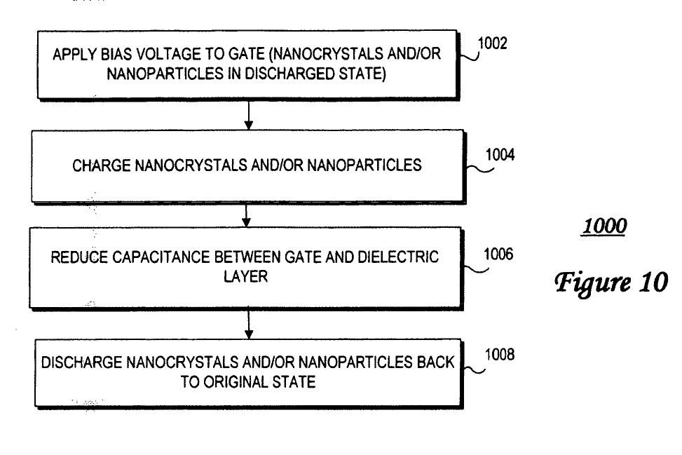

FIG. 10 is a flowchart illustrating a method 1000 of operating the two-terminal solid-state memory device 100 and/or 800 according to an embodiment of the present invention. The memory device 100 and/or 800 may include a first capacitance existing between the dielectric layer 104/804 and the gate electrode 108/808. The first capacitance may represent a discharged state of the nanocrystals and/or nanoparticles 106/806.

In a block 1002, a bias voltage may be applied to the gate electrode 108. In one embodiment, the bias voltage may be a positive voltage. In an alternative embodiment, the bias voltage may be a negative voltage.

In a block 1004, the nanocrystals and/or nanoparticles 106/806 may be charged in response to applying the bias voltage to the gate electrode 108.

In a block 1006, the first capacitance existing between the dielectric layer 104/804 and the gate electrode 108/808 may be reduced to a second capacitance in response to the charging of the nanocrystals and/or nanoparticles 106/806. In embodiments of the present invention, the ratio between the first and the second capacitances is sufficient to distinguish the “on” state of the memory device 100/800 and the “off” state of the memory device 100/800.

In a block 1008, the nanocrystals and/or nanoparticles 106/806 may be discharged back to the first capacitance. In one embodiment, to discharge the nanocrystals and/or nanoparticles 106/806 a low bias voltage with a polarity opposite of the charging bias voltage may be applied to the gate electrode 108. In an alternative embodiment, to discharge the nanocrystals and/or nanoparticles 106/806 the nanocrystals and/or nanoparticles 106/806 were illuminated with ultraviolet (UV) light at a wavelength of 365 nm, for example. In still another embodiment, to discharge the device 100/800 was annealed at a low temperature, such as 100° C., for example.

The operations of the methods 200 and 900 have been described as multiple discrete blocks performed in turn in a manner that may be most helpful in understanding embodiments of the invention. However, the order in which they are described should not be construed to imply that these operations are necessarily order dependent or that the operations be performed in the order in which the blocks are presented. Of course, the methods 200 and 900 are example processes and other processes may be used to implement embodiments of the present invention.

A machine-accessible medium with machine-readable data thereon may be used to cause a machine, such as, for example, a processor (not shown) to perform the methods 200 and 1000. A machine-accessible medium includes any mechanism that may be adapted to store and/or transmit information in a form accessible by a machine (e.g., a computer, network device, personal digital assistant, manufacturing tool, any device with a set of one or more processors, etc.). For example, a machine-accessible medium includes recordable and non-recordable media (e.g., read only memory (ROM), random access memory (RAM), magnetic disk storage media, optical storage media, flash memory devices, etc.), as well as electrical, optical, acoustic, or other form of propagated signals (e.g., carrier waves, infrared signals, digital signals, etc.).

In the above description, numerous specific details, such as, for example, particular processes, materials, devices, and so forth, are presented to provide a thorough understanding of embodiments of the invention. One skilled in the relevant art will recognize, however, that the embodiments of the present invention may be practiced without one or more of the specific details, or with other methods, components, etc. In other instances, structures or operations are not shown or described in detail to avoid obscuring the understanding of this description.

Reference throughout this specification to “one embodiment” or “an embodiment” means that a particular feature, structure, process, block, or characteristic described in connection with an embodiment is included in at least one embodiment of the present invention. Thus, the appearance of the phrases “in one embodiment” or “in an embodiment” in various places throughout this specification does not necessarily mean that the phrases all refer to the same embodiment. The particular features, structures, or characteristics may be combined in any suitable manner in one or more embodiments.

The terms used in the following claims should not be construed to limit embodiments of the invention to the specific embodiments disclosed in the specification and the claims. Rather, the scope of embodiments of the invention is to be determined entirely by the following claims, which are to be construed in accordance with established doctrines of claim interpretation.

1. An apparatus, comprising:
a two-terminal solid-state memory device having:
a semiconductor substrate;
a dielectric layer disposed on the substrate;
a plurality of nanocrystals and/or nanoparticles disposed substantially throughout the dielectric layer;
a gate electrode disposed on the dielectric layer; and
a metal electrode on the backside of the substrate.

2. The apparatus of claim 1, wherein the semiconductor substrate is formed of silicon and/or germanium.

3. The apparatus of claim 1, wherein the dielectric layer is formed of SiO₂.

4. The apparatus of claim 1, wherein the gate electrode is comprised of aluminum, gold, silver, and/or copper.

5. The apparatus of claim 1, wherein the gate electrode is comprised of polysilicon.

6. The apparatus of claim 1, wherein the nanoparticles and/or nanocrystals comprise semiconductor material, an individual nanoparticle and/or nanocrystal having size between approximately one nanometer and one hundred nanometers.

7. The apparatus of claim 1, wherein the nanoparticles and/or nanocrystals comprise metal, an individual nanoparticle and/or nanocrystal having size between approximately one nanometer and one hundred nanometers.

8. A method, comprising:
fabricating a two-terminal solid-state memory device by:
forming a dielectric layer on a semiconductor substrate;
introducing nanocrystals and/or nanoparticles substantially throughout the dielectric layer; and
forming a gate electrode gate electrode on the dielectric layer.

9. An apparatus comprising:
a flexible two-terminal organic memory device based on nanocrystals and/or nanoparticles having:
a flexible substrate;
an organic semiconductor layer or conductive organic layer disposed on the substrate;
an organic insulating layer disposed on the semiconductor or conductive organic layer;
a plurality of nanocrystals and/or nanoparticles embedded throughout the organic insulating layer; and
a conductive organic gate electrode disposed on the organic insulating layer.

10. The apparatus of claim 9, wherein the substrate is formed of polymer and/or plastic.

11. The apparatus of claim 9, wherein the nanocrystal and/or nanoparticle comprise metal or semiconductor material.

12. The apparatus of claim 9, wherein the nanoparticles and/or nanocrystals are embedded throughout the organic insulating layer with a high concentration.

13. The apparatus of claim 9, wherein the nanoparticles and/or nanocrystals, an individual nanoparticle and/or nanocrystal having size between approximately one nanometer and one hundred nanometers.

14. The apparatus of claim 9, wherein the organic semiconductor layer or conductive organic layer comprise anthracene, tetracene, and/or pentacene.

15. The apparatus of claim 9, wherein the organic semiconductor layer or conductive organic layer comprises a conductive polymer.

16. The apparatus of claim 9, wherein the conductive organic gate electrode comprises a conductive polymer.

17. A method comprising:
operating a two-terminal organic memory device having a first terminal being a gate and a second terminal being an organic conductive or semiconductor film by:
applying a voltage to the gate;
charging nanocrystals and/or nanoparticles embedded throughout an insulating layer to a first state in response to the applied voltage, the first state to represent an “off” state for the memory device; and
discharging the nanocrystals and/or nanoparticles embedded throughout the insulating layer to a second state, the second state to represent an “on” state for the memory device.

18. The method of claim 17, further comprising applying a second voltage to the gate to discharge the nanocrystals and/or nanoparticles embedded throughout the insulating layer, wherein the second voltage is of a polarity opposite a polarity of the applied voltage.

19. The method of claim 17, further comprising illuminating the memory device with ultraviolet (UV) light to discharge the nanocrystals and/or nanoparticles embedded throughout the insulating layer.

20. The method of claim 17, further comprising heating the memory device with a low temperature to discharge the nanocrystals and/or nanoparticles embedded throughout the insulating layer.

21. The method of claim 17, further comprising heating the memory device to approximately 100 degrees Centigrade.

22. A method, comprising:
fabricating a two-terminal flexible memory device by:
forming a conductive organic or a organic semiconductor layer on the flexible substrate;
forming a organic dielectric layer on the conductive organic or organic semiconductor layer; and
introducing nanocrystals and/or nanoparticles into the dielectric layer; and depositing conductive organic layer for a gate electrode.
